(19) United States
(12) Patent Application Publication
(10) Pub. No.: US 2024/0136229 A1
(43) Pub. Date: Apr. 25, 2024

(54) CHANNEL UNIFORMITY HORIZONTAL GATE ALL AROUND DEVICE

(71) Applicant: Applied Materials, Inc., Santa Clara, CA (US)

(72) Inventors: Jody FRONHEISER, Santa Clara, CA (US); Sai Hooi YEONG, Santa Clara, CA (US); Benjamin COLOMBEAU, Santa Clara, CA (US); Balasubramanian PRANATHARTHIHARAN, Santa Clara, CA (US); Lequn LIU, Santa Clara, CA (US)

(21) Appl. No.: 18/462,242

(22) Filed: Sep. 6, 2023

Related U.S. Application Data
(60) Provisional application No. 63/416,652, filed on Oct. 17, 2022.

(51) Int. Cl. H01L 21/8234; H01L 21/02; H01L 29/15; H01L 29/423

(52) U.S. Cl. CPC H01L 21/823412; H01L 21/02507; H01L 29/15; H01L 29/42392

(57) ABSTRACT

A method of forming a multi-layer semiconductor device on a substrate includes forming a superlattice of a plurality of alternating first layers composed of a first material and second layers formed of a second material, removing the second layers of the superlattice, etching the first material layers to form trimmed first layers therefrom, wherein the quantity of material removed from different ones of the first layers are different amounts, forming a capping layer over the first layers, measuring at least one of the distance between the capping layers formed on the different ones of the first layers, the thicknesses of the different ones of the capping layers formed on different ones of the trimmed first layers, and the different thicknesses of the combined thickness of different ones of the trimmed first layers and the capping layer formed thereover, and based on differences in the measurements, calculating a new thickness of the etched first layers.

### CROSS-REFERENCE TO RELATED APPLICATIONS

This application claims benefit of U.S. provisional patent application Ser. No. 63/416,652, filed Oct. 17, 2022, which is herein incorporated by reference.

### BACKGROUND

### Field

Examples described herein generally relate to the field of semiconductor processing, and more specifically, to integrated semiconductor processing solutions.

### Description of the Related Art

Reliably producing nanometer and smaller features is one of the key technology challenges for next generation very large scale integration (VLSI) and ultra large-scale integration (ULSI) of semiconductor devices. As the limits of circuit technology are pushed, the shrinking dimensions of VLSI and ULSI technology have placed additional demands on processing capabilities. As the dimensions of the integrated circuit components are reduced (e.g., in nanometer dimensions), the materials and processes used to fabricate components are generally carefully selected in order to obtain satisfactory levels of electrical performance.

One known device structure is the horizontal all around gate structure, also referred to as an hGGA, in which a plurality of semiconductor channels are below a gate electrode and stacked one over the other to extend between the source and drain of an individual semiconductor device. The semiconductor channels are configured in part by epitaxially forming a plurality of alternating layers of the semiconductor material and a sacrificial material to form a superlattice structure, and patterning that superlattice structure into a plurality of superlattice fins or mesas having a width slightly larger than the length of the finished channels. The sacrificial material is removed to leave behind individual lengths of the semiconductor material which will form individual channels, and these individual lengths or wires of the semiconductor material are then trimmed to the desired channel length, which also results in removal of a portion of each wire on the other surfaces thereof. A capping layer, for example an additional semiconductor layer is then formed on each wire, each wire is then coated with a high k value dielectric, and then a work function tuning material is formed thereover. The high k value dielectric and the work function tuning material are thus deposited on the surface of each wire facing the underlying substrate, as well as the surface of the wire on the opposite side of the wire. In a known structure, the first semiconductor layer in the superlattice structure is silicon, for example single crystal silicon which may be a doped single crystal silicon material epitaxially grown on an underlying single crystal substrate or single crystal layer. In this known structure, the sacrificial material is, for example, silicon germanium, which can be epitaxially grown or formed by a vapor deposition technique on an underlying silicon crystal structure. The use of silicon and silicon germanium allows the silicon layers of the known structure to be formed as single crystal layers. The capping layer may be, for example, a silicon germanium layer.

To provide device-to-device repeatable functional performance, variation of the thicknesses of the silicon layers, silicon germanium layers, and thus the high k value dielectric and the work function tuning layer material layer formed between the adjacent layers of silicon surrounded by silicon germanium, should be minimized. However, it has been found that the thicknesses of these layers can vary significantly in a stack of silicon, silicon germanium, high k value dielectric and work function tuning layers. This has led to less than desirable performance and repeatability in performance of these structures.

### SUMMARY

Embodiments of the disclosure include a method for semiconductor processing. In one aspect hereof, a method of forming a semiconductor device includes:
forming a first superlattice on a first substrate, the first superlattice comprising alternating sub-layers of a first material comprising a semiconductor and sub-layers of a second material, wherein the thicknesses of the first material sub-layers are a first thicknesses and the thicknesses of the second material sub-layers are a second thickness, wherein at least a first sub layer of the first material and a second sub layer of the first material are formed in the first superlattice, the second sublayer of the first material interposed between the first sublayer of the first material and the substrate;
removing the sub-layers of the second material from the first superlattice;
etching the first and second sub-layers of the first material of the first superlattice to remove a portion of the first material thereof and form a first trimmed sub-layer of the first material and a second trimmed sub-layer of the first material, wherein the amount of first material removed from the first sub-layer of the first material is greater than the amount of material removed from the second sub-layer of the first material; and
depositing a capping layer over the first trimmed sub-layer of the first material of the first superlattice, over the second trimmed sub-layer of the first material of the first superlattice, and on an exposed surface of the substrate;
measuring the distance between the capping layer on the first sub-layer and the capping layer on the second sublayer, and the distance between the capping layer on the second sub-layer and the capping layer on the substrate, and determining a first difference between those distances;
forming a second superlattice on a second substrate, the second superlattice comprising alternating sub-layers of the first material comprising a semiconductor and sub-layers of the second material, wherein the thicknesses of the first material sub-layers are a first thicknesses and the thicknesses of the second material sub-layers are a second thickness, wherein at least a first sub layer of the first material and a second sub layer of the first material are formed in the second superlattice, the second sublayer of the first material interposed between the first sublayer of the first material and the second substrate;
removing the sub-layers of the second material from the second superlattice and the second substrate;
etching the first and second sub-layers of the first material of the second superlattice to remove a portion of the first material thereof and form a first trimmed sub-layer of the first material and a second trimmed sub-layer of the first material, wherein the process conditions used to remove the portions of the first sub-layer of the first material and of the second sub-layer of the first material are different than those used to remove portions of the first sub-layer of the first material and the second sublayer of the first material of the first superlattice; and
depositing a capping layer over the first trimmed sub-layer of the first material of the second superlattice and over the second trimmed sub-layer of the first material of the second superlattice and on an exposed surface of the substrate;
wherein, the difference between the distance between the capping layer on the first sub-layer of the first material and the capping layer on the second sublayer of the first material of the second superlattice and the distance between the capping layer on the second sub-layer of the first material of the second superlattice and the capping layer on the second substrate is less than the first difference.

In another aspect hereof, a method of forming a semiconductor device on a substrate includes:
forming a superlattice on the substrate, the superlattice comprising alternating sub-layers of a first material comprising a semiconductor and sub-layers of a second material, wherein the thicknesses of at least a first sub-layer of the first material layers and a second sub-layer of the first material have different thicknesses, the second sublayer of the first material interposed between the first sublayer of the first material and the substrate;
removing the second material sub-layers from the superlattice;
etching the first sub layer of the first material and the second sublayer of the first material, such that a different quantity of first material is removed from the first sub layer of the first material compared to the amount of material removed from second sublayer of the first material; and
depositing a capping layer over the etched first sub layer of the first material and over the etched second sublayer of the first material, wherein the thickness of the capping layer deposited on the first sub layer of the first material is different from the thickness of the capping layer deposited on the second sub layer of the first material.

In another aspect, a method of forming a multi-layer semiconductor device includes:
providing a first substrate;
forming a superlattice on first substrate, the superlattice comprising a plurality of alternating first layers composed of a first material and second layers formed of a second material;
selectively removing the second layers of the superlattice;
exposing the first layers of the superlattice to an etchant using first process conditions and removing a portion of the first material therefrom to form trimmed first layers therefrom, wherein the quantity of material removed from different ones of the first layers are different amounts;
forming a capping layer over the first layers in the superlattice stack;
measuring at least one of the distance between the capping layers formed on the different ones of the first layers, the thicknesses of the different ones of the capping layers formed on different ones of the trimmed first layers, and the different thicknesses of the combined thickness of different ones of the trimmed first layers and the capping layer formed thereover; and
based on the differences between at least one of the distance between the capping layers formed on the different ones of the first layers, the thicknesses of the different ones of the capping layers formed on different ones of the trimmed first layers, and the different thicknesses of the combined thickness of different ones of the trimmed first layers and the capping layer formed thereover, calculating a new thickness of the trimmed first layers.

### BRIEF DESCRIPTION OF THE DRAWINGS

So that the manner in which the above recited features of the present disclosure can be understood in detail, a more particular description, briefly summarized above, may be had by reference to examples, some of which are illustrated in the appended drawings. It is to be noted, however, that the appended drawings illustrate only some examples and are therefore not to be considered limiting of the scope of this disclosure, for the disclosure may admit to other equally effective examples.

FIG. 1 is a partial sectional view of a horizontal gate all around structure.

FIGS. 2a to 2d are schematic sectional views showing the effect of certain actions in the processing of a horizontal gate all around structure.

FIGS. 3a to 3d are schematic sectional views showing the effect of a first alternative series of actions in the processing of a horizontal gate all around structure.

FIGS. 4a to 4d are schematic sectional views showing the effect of a first alternative series of actions in the processing of a horizontal gate all around structure.

FIG. 5 is a schematic top-view diagram of an example multi-chamber processing system according to some examples of the present disclosure.

FIG. 6 is a cross-sectional view of a processing chamber that may be used to perform a cleaning process according to some examples of the present disclosure.

FIG. 7 is a cross-sectional view of a processing chamber that may be used to perform a selective etch process and trimming process according to some examples of the present disclosure.

FIG. 8 is a cross-sectional view of a thermal processing chamber that may be used to perform epitaxial growth according to some examples of the present disclosure.

To facilitate understanding, identical reference numerals have been used, wherever possible, to designate identical elements that are common to the figures.

### DETAILED DESCRIPTION

Generally, examples described herein relate to semiconductor device structures, methods of forming the semiconductor structures, and semiconductor processing systems for forming individual semiconductor layers in a superlattice, isolating the individual semiconductor structures in the superlattice from one another with a gap therebetween, trimming those semiconductor layers, and forming capping layers on the trimmed layers. In one aspect hereof, the difference in the spacing between the isolated semiconductor structures is reduced. In one aspect, the individual semiconductor layers spaced from one another by a gap, as an intermediate structure in the manufacture of a device, are single crystal silicon layers. Additionally, the capping layers can be provided as silicon germanium layers epitaxially grown or formed on the individual single crystal silicon layers. Such reduction of the variation in the spacing or gap between the individual trimmed semiconductor layers may be provided, for example, by initially forming different ones of the layers to have different thicknesses, such that the variation in the material removal rate and material removed from different ones of the layers during trimming results in a more uniform trimmed thickness of the semiconductor layers. In another aspect, variation in the parameters of the trimming process are used to result in a more uniform trimmed thickness of the semiconductor layers. The structures formed by such processing can be implemented in, for example, horizontal gate all around field effect transistors (hGAA FETs). The methods and semiconductor processing systems can provide an integrated solution to trim the layers to be trimmed, and thereafter epitaxially grow capping layers on the trimmed layers.

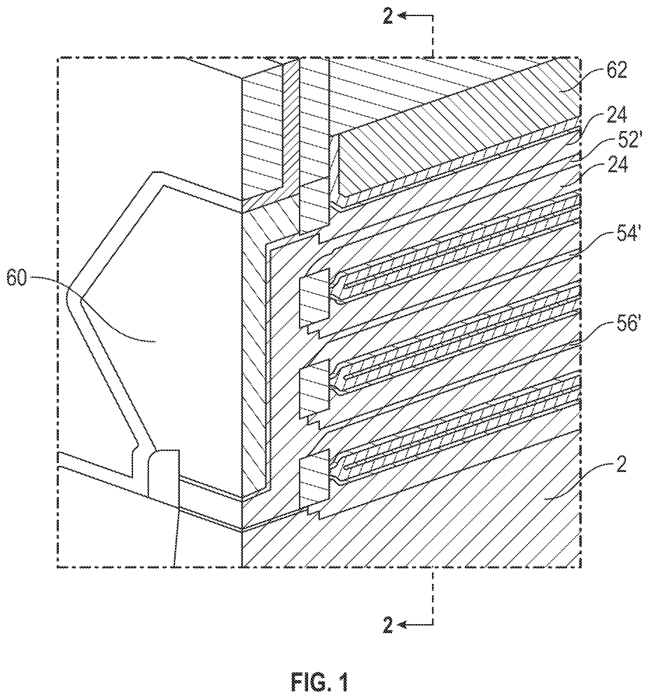

Referring initially to FIG. 1, there is shown a partial sectional view of a horizontal gate all around structure, or HGAA, formed on a substrate 2. Only one side of the HGAA is shown, and one skilled in the art would recognize that the device includes structure, including a source or drain, on the opposed side of the structure from the source or drain 60 shown.

Here, a plurality of “wires” formed of a semiconductor, for example of epitaxially grown or deposited single crystal silicon, extend laterally or horizontally form the source or drain 60, to the other of the source or drain to the right of the figure (not shown). Each of the wires is formed as a post-trim wire preform 52′ to 56′ as will be described herein. Each wire, here the post trim wire preforms 52′ to 56′, is capped by a surrounding capping layer 24. The capping layer is preferably epitaxially grown on and surrounds the post trim wire preforms 52′ to 56′, and also grown over the upper surface of the substrate 2. The capping layer is, for example, silicon germanium. Additional gate functional layers are grown or deposited on the capping layer 24, and a gate 62 is formed thereover. Additional intermediate layers such as barrier layers, high k dielectric layers and work function tuning layers, or other layers may be incorporated into the stack of layers shown in FIG. 1. Thus, the structure of FIG. 1 is provided as an example of a HGAA structure, and not limiting of such a structure.

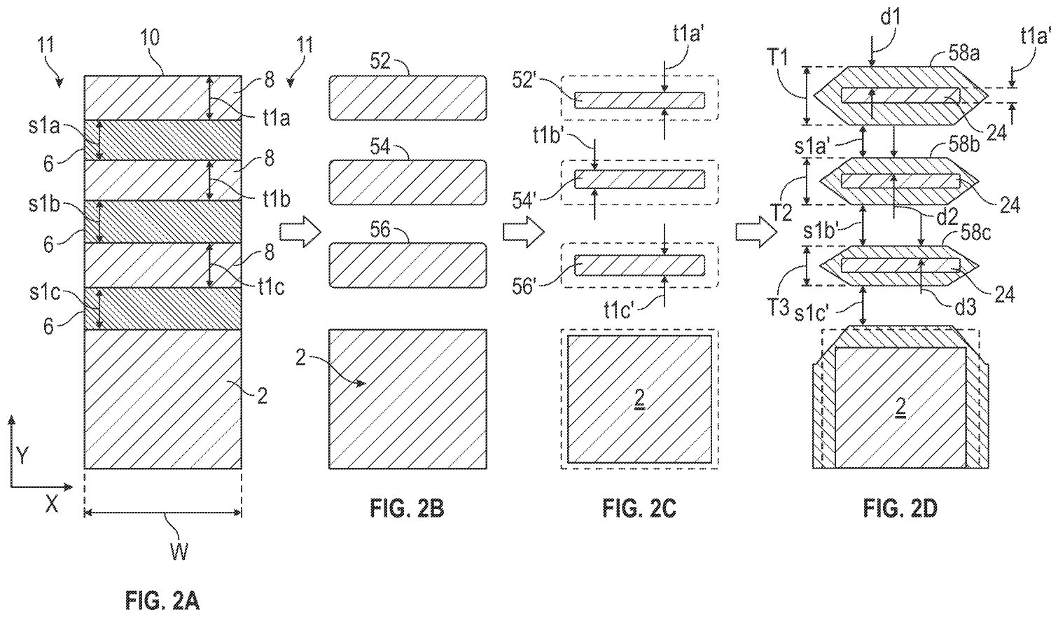

FIGS. 2a to 2d are a sectional view of a portion of the HGGA structure of FIG. 1, showing the results of process actions used to form the stack of post trim wire preforms 52′, 54′, 56′, and the capping layers 24 for an HGAA structure. Referring to FIGS. 2a to 2d, the results of the sequence of operations performed for isolating the individual semiconductor layers for a wire stack from individual layers of the superlattice, trimming the individual semiconductor layers isolated from the superlattice, and forming a capping layer, for example a secondary semiconductor layer, over the trimmed semiconductor layer is shown in sequence. Here, the superlattice is formed by sequentially growing a plurality of alternating layers of a sacrificial material such as a silicon germanium layer 6, and a semiconductor layer, such as a silicon layer 8, over a substrate 2. A first sacrificial layer is epitaxially grown on the substrate 2, a first semiconductor layer is epitaxially grown on the first sacrificial layer, layer, and subsequent sacrificial layers and semiconductor layers are epitaxially grown in an alternating fashion thereover.

In FIG. 2a, the superlattice from which the fin or mesa 10 is singulated over a substrate includes semiconductor layers as doped single crystal silicon and sacrificial layers as silicon germanium. The thickness of each of the semiconductor layers is, within deposition tolerance, formed to be the same for each of the semiconductor layers. In FIG. 2a, the thickness of each sacrificial layer is, within deposition tolerance, formed to be of the same thickness for each of the sacrificial layers. The thicknesses of the semiconductor layers and the sacrificial layers can be the same, or different.

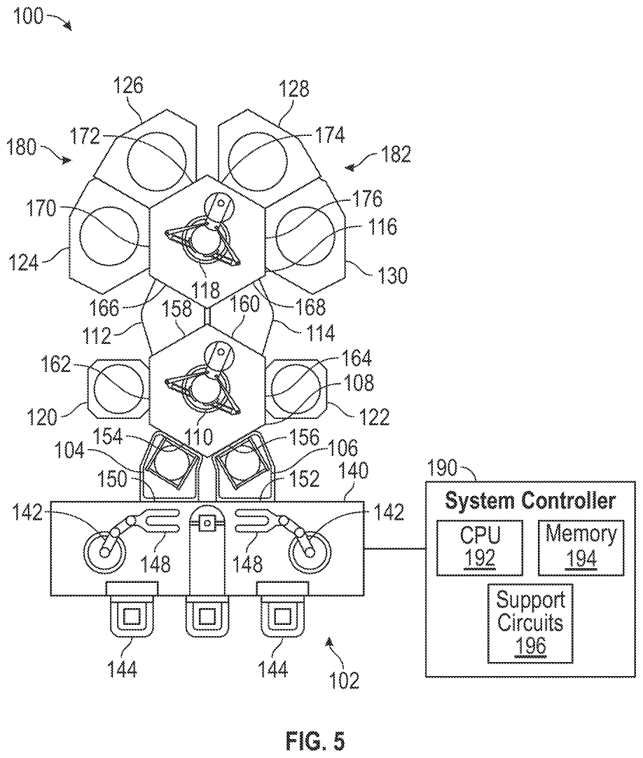

Initially, the left hand sides of FIGS. 2 to 4, here FIGS. 2a, 3a and 4a, depict a sectional view of a single superlattice fin or mesa 10 of a plurality of fins or mesas defined from a superlattice stack by a reactive ion etching process. It is to be understood that one or more such fins or mesas 10 (extending inwardly and outwardly of the plane of FIGS. 5 to 7) may be aligned with their side walls facing one another over the width of the trench 11 etched inwardly of the superlattice in the Y direction and having a trench width in the X direction of FIGS. 2a to 4a. For convenience of illustration, only one of the fins or mesas 10 are shown in FIGS. 2a to 4a. The trenches 11 define or singulate the fins or mesas 10 having alternating silicon germanium layers 6 and silicon layers 8 from a superlattice (not shown) of silicon layers 8 and silicon germanium layers 6. This same etch step can be used to etch the trench 11 inwardly of the underlying single crystal silicon substrate 2 to define isolated linear segments or mesas of the semiconductor substrate 2 (extending inwardly and outwardly of the plane of FIGS. 2a to 4a) under each of the fins or mesas 10. Here, the initial thicknesses of the silicon layers t1a, t1b and t1c in the superlattice in the y direction of FIG. 5, and thus in the fin or mesa 10, are equal to one another, within deposition tolerance or deposition capability thereof. In other words, in the original superlattice the thicknesses t1a, t1b and t1c of the silicon layers 8 are related such that t1a=t1b=t1c. Likewise the thicknesses s1a, s1b and s1c of the sacrificial silicon germanium layers in the Y direction of FIG. 2a in the superlattice, and thus in the fin or mesa 10, are equal to one another within deposition tolerance or deposition capability thereof. In other words, in the original superlattice the thicknesses s1a, s1b and s1c of the sacrificial silicon germanium layers 6, and thus the spacings between the individual silicon layers 8 and the lowermost silicon layer 8 and the substrate, are related such that s1a=s1b=s1c

After the fins or mesas 10 are defined from the superlattice of alternating silicon germanium and silicon layers 6, 8, the portions of the sacrificial silicon germanium layers 6 isolated therein are removed from the stack or fin 10 using a selective removal process with the result shown in FIG. 2b. The silicon germanium layers 6 are selectively removed by the selective etch process (e.g., a selective isotropic etch process), for example using an etching gas composed of the NF3, which is disassociated into F radicals and F₂ in a remote plasma source and then flowed over the substrate 2 to penetrate the trenches and contact and selectively remove the silicon germanium of the silicon germanium layers 6. This leaves individual, now singulated, portions of the silicon layers 8 in each fin or mesa 10, here three wire preforms 52, 54 and 56 composed of silicon, spaced and isolated from one another in the Y direction of FIG. 2b by the thickness of each removed silicon germanium sacrificial layer 6, here s1a and s1b, which are equal or substantially equal thicknesses. In other words the spacing between the individual wore preforms 52, 54 and 56 is equal to the original thicknesses of the removed silicon germanium layers, such. The third wire preform 56 closest to the isolated mesa of the substrate 2 is likewise spaced from the facing substrate 2 upper surface by the thickness s1c of the removed sacrificial silicon germanium layer 6. Thus, the spacing in the Y direction between the facing surfaces of the semiconductor substrate 2 and the third wire preform 56, between the second and third wire preforms 54, 56, and between the first and second wire preforms 52, 54 are substantially the same distance or span, substantially equal to the thicknesses s1a, s1b and s1c of the silicon germanium layers 6 previously extending therebetween, and s1a=s1b=s1c.

After the individual first to third wire preforms 52, 54 and 56 are isolated from the silicon layers 8 of the superlattice, they are trimmed, in other words reduced in size. Trimming is performed using an etch process, for example a remote plasma etch process, where the reactive etch gas (es) is at least partially ionized in a plasma located remotely from the substrate, and radicals of the etch reaction gas (es) are directed or flow toward the substrate to etch the silicon on the first through third wire preforms 52 to 56 to yield first through third post trim wire preforms 52′, 54′ and 56′ smaller in thickness in the Y direction of FIG. 2c and smaller in width in the X direction of FIG. 2c than the first through third wire preforms 52-56 as is shown in FIG. 2b. Here, the original size of each of the first through third wire preforms 52-56 is shown in dashed outline surrounding the corresponding trimmed state thereof in FIG. 2c.

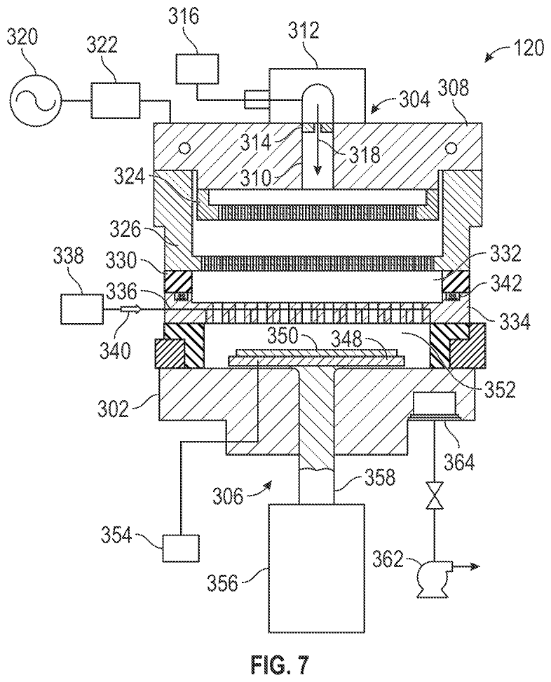

Trimming of the first through third wire preforms 52-56 can be performed with the processing chamber 120 illustrated in FIG. 7, the trimming process including flowing a first etch gas, which may include one or more of nitrogen trifluoride (NF3), a mixture of nitrogen trifluoride (NF3) and helium (He), or the like, from the gas source 316 by flow 318, and flowing a second etch gas, which may include one or more of nitrogen trifluoride (NF3) or the like, from the gas source 338 by flow 340. A mixture of nitrogen trifluoride (NF3) and helium (He) can be in a ratio in a range from 1:350 (NF3:He) to 1:120 (NF3:He), which mixture can be flowed from gas source 316 at a flow rate in a range from 5000 sccm to 7000 sccm, such as with a flow rate of trifluoride (NF3) in a range from 10 sccm to 25 sccm, and a flow rate of helium (He) in a range from about 3000 sccm to 3500 sccm. A pressure in the chamber 120 can be maintained in a range from 0.25 Torr to about 2 Torr. A power applied by the RF power source 320 can be in a range from about 10 W to about 50 W at a frequency from about 10 MHz to about 50 MHz (e.g., 13.56 MHz). This can be performed in a Selectra® Etch chamber available from Applied Materials of Santa Clara, Calif. wherein the gases are energized into a plasma in the lid assembly 304 and then the energized NF3 and H2 gases are flowed onto the substrate.

Here, this trim processing results in the thickness t1a′ of the first post trim wire preform 52′ to be slightly less than that of the thickness t1b′ of the second post trim wire preform 54′, which is slightly less than the thickness t1c′ of post trim wire preform 56′. In other words, the trimmed wire preform thicknesses t1a′, t1b′ and t1c′ have the relationship t1c′>t1b′>t1a′. It is believed that this difference in thickness, where the wire preforms 52, 54 and 56 were of the same initial thickness t1a=t1b=t1c, is a result of depletion of the etchant chemistry in the depth or Y-direction of the trench 11 between adjacent fins or mesas 10 during the trimming process. In other words, the relative availability of the etchant is greater at the first wire preform 52 furthest from the underlying substrate 2 as compared to that available at the second wire preform 54, as a result of a portion thereof being consumed in the etch based trimming of the first wire preform 52. Likewise, it is believed that the relative availability of the etchant at the third wire preform 56 which is closest to the substrate 2 and thus the deepest one in the trench 11 is less than that at the second wire preform 54, because of the portion thereof consumed in the etch based trimming of the first and second wire preforms 52, 54.

After the post trim wire preforms 52′, 54′ and 56′ are prepared, a final wire 58 structure is completed by deposition of an additional second semiconductor layer thereover, here a capping layer 24 of silicon germanium as previously described herein. The resulting final wire 58 structure thus includes three individual wires 58, here first to third final wires 58a, 58b and 58c composed of a corresponding silicon post trim wire preform 52′ to 56′ and the overlying deposited capping layer 24 of silicon germanium. The first to third final wires 58a, 58 b and 58c are spaced from one another and spaced from the underlying semiconductor substrate 2 by spacing distances s1a′ to s1c′. Here, the thickness d1 in the Y direction of FIG. 2d of the capping layer 24 deposited on the on the first post trim wire preform 52′ is thicker than the thickness d2 in the Y direction of FIG. 2d of the capping layer 24 grown on the second post trim wire preform 54′. Similarly, the thickness d3 in the Y direction of FIG. 2d of the capping layer 24 on the third post trim wire preform 56′ is thinner than that grown on both the first and the second post trim wire preforms 52, 54. In other words, the relationship of the capping layer 24 thicknesses d1, d2 and d3 is d1>d2>d3. As a result of this and the different thicknesses of the post trim wire preforms 52′, 54′ and 56′, the thicknesses T1 to T3 of the final wires 58a, 58b and 58c are different in the Y direction of FIG. 2d, and the spacings s1a′ to s1c′ in The Y direction of FIG. 2d between the first to third final wires 58a to 58c and between third final wire 58c and the facing surface of the capping layer 24 on the substrate 2 are different. Here, the spacing s1a′ between the facing surfaces of the first and second final wires 58a, b is less the spacing s1b′ between the facing surfaces of the second and third final wires 58b, c. The spacing s1c′ between the facing surfaces of the third final wire 58c and the facing surface of the capping layer on substrate 2 is greater than spacing s1b′. In other words, s1c′>s1b′>s1a′. As a result, the thicknesses of the high k dielectric layer and work function tuning layers subsequently formed to fill the space between the adjacent first and third final wires 58a-58c and between third final wire 58c and the facing surface of the capping layer 24 on the substrate 2 will vary with respect to each other, and the electrical performance of each of the first to third wires 58a-c operating as a channel will be different. Additionally, the space between two adjacent ones of the first to third final wires 58a-c may become too small to accommodate a thickness of the high k dielectric layer, work function tuning layer, or both, which are required to enable the desired performance of one or more of the first to third final wires 58a-c as a functional channel.

Herein are provided mechanisms and processes to overcome these variations of layer thicknesses and spacings, to yield more repeatable and more uniform spacings between the final wires, and more uniform thicknesses of the final wires. Here, this is provided at least in part by tuning of the thicknesses of the individual first to third post trim wire preforms 52′ to 56′, and ensure a minimum desired spacing is maintained between the first to third final wires 58a to 58c after the capping layer is formed. Specifically, the thicknesses of the silicon layers 6 in the superlattice, or the trim processing of the first to third post trim wire preforms 52′ to 56′, or both, are adjusted or modified to yield a resulting stack of first to third final wires 58a to 58c spaced from one another in the Y direction with a more uniform space or distance therebetween in the Y direction, and a more uniform thickness of the final wires 58a to 58c.

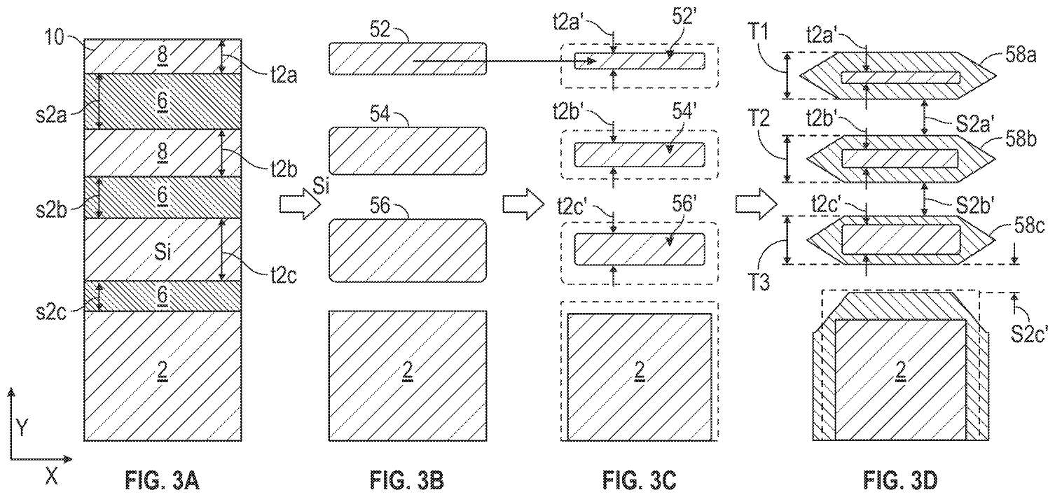

Referring to FIGS. 3a to 3d, there is shown schematically the results of a sequence of process actions used to reduce the thickness variation between the first to third final wires 58a to 58c, and thus reduce the variation of the spacings s1a′ and s1b′ between the first to third final wires 58a-c and the spacing s1c′ between the third final wire 58c closest to the substrate 2 and the facing surface of the capping layer 24 on the substrate 2. In the process used to form the first to third final wires 58a-58c of FIGS. 2a to 2d, the variation of the thicknesses of the capping layer 24 and the trimmed wire preforms contribute to the difference in the thicknesses in the Y direction of the first to third final wires 58a to 58c. Here, to compensate for this variation between the adjacent finished wires 58a to 58c and between the third finished wire 58c and the surface of the capping layer 24 on the substrate 2, the relative thicknesses in the Y direction of the individual silicon germanium layers 6 and the silicon layers 8 in the superlattice stack are changed as compared to those in FIG. 2a. Here, on trimmed wire preforms where the capping layer inherently deposits to a thinner thickness than other trimmed wire preforms, the thickness of the silicon layer 8 in the superlattice is increased relative to other silicon layers 8 in the superlattice and greater than the thickness thereof in FIG. 2a. On trimmed wire preforms where the capping layer 24 deposits to a greater thickness than on other ones of the trimmed wire preforms, the silicon layer 8 is formed thinner relative to other silicon layers 8 in the superlattice and thinner than its thickness in FIG. 2a

To meet the same design constraints as those desired for to the HGAA structure partially constructed in FIGS. 2a to 2d, the total thickness of the superlattice composed of the stack of silicon germanium layers 6 and silicon layers 8 should remain the same as that of FIG. 2a within design and deposition tolerances. Likewise, the centerlines (not shown) in the X direction of first to third final wires 58a-c should preferably be located the same distance in the Y direction from the upper surface of the substrate as they are in FIG. 2a. Because of these constraints, if the thickness one of the three sets of layers of the silicon layers and silicon germanium layers 8, 6 is changed, the thickness of the other of the silicon and silicon germanium layers 8, 6 must also be changed, but in an opposing way. The desired end result is to provide a plurality of final wires 58 spaced from one another, and from the surface of the capping layer 24 on the substrate 2, by the same or nearly the same distance, and that the final wire thicknesses be more uniform than those of FIG. 2d.

Here, as described herein, the thicknesses of the silicon layers 8 are selected such that the thicknesses of the final wires 58a-58c are relatively equal, and the thickness of the silicon germanium layers 6 are selected to result in a relatively equal spacing between the final wires 58a-58c and between the final wire 58c and the facing surface of the capping layer 24 on the substrate 2. Thus, different silicon layers 8 can have different thicknesses in the superlattice, and different silicon germanium layers 6 can have different thicknesses, as shown in FIG. 3a. Then the silicon germanium layers 6 are selectively removed in the same manner as described herein with respect to FIGS. 2a to 2d to the result shown in FIG. 3b. Here, the spacings between the individual wire preforms 52-56 is that of the thickness of the silicon germanium layers 6 that have been removed. Note here, these spacings are not equal to one another. Also, the thicknesses of the wore preforms 52-56 re different from one another, in contrast to those shown in FIG. 2c, which are equal to one another. Then, the wire preforms 52-56 are isotopically etched in the same manner as described herein with respect to FIGS. 2a to 2d, and post trim wire preforms 52′ to 56′ having different thicknesses from one another result as shown in FIG. 3c. Then, using the same epitaxially deposition process to form the capping layer 24 as was used to form the capping layers 24 of different thicknesses shown in FIG. 2d, each of the post trim wire preforms 52′-56′ and the exposed surface of the substrate 2 are now covered in the capping layer 24. Using the same process conditions as used to form the capping layers 24 of FIG. 2d, the same, or nearly the same, non-uniformity of the thickness of the capping layers 24 on the different ones of the post trim wire preforms 52′ 56′ is formed in FIG. 3d as was formed in FIG. 2d. Because the thicknesses of the post trim wire preforms 52′-56′ have been modified as compared to those in FIGS. 2c and 2d, the resulting final wire thicknesses 58a-58c are the same or substantially the same, and the spacings between the final wires 58a-58c and between final wire 58c and the facing surface of the capping layer 24 on the substrate 2 are the same or substantially the same. Depending on the requirements of the application of the HGAA, substantially the same is a difference between the wire thicknesses, spacings, or both, within a design tolerance range.

To implement the resulting structure shown in FIGS. 3a to 3d, a first order assumption is made that the chemistry depletion effects which cause the differences in the thicknesses of the post trim wire preforms 52′-56′ as shown in in FIG. 2c, and that cause the differences in the deposited thickness of the capping layer 24 on the post trim wire preforms 52′-56′ as shown in FIG. 2d, will not change significantly despite changing the initial thicknesses of the silicon layers 8 in the superlattice as compared to those shown in FIG. 2a. Additionally, based on the design specifications of the HGAA device, a minimum spacing between the final wires 58-58c is known. Thus, the thicknesses of the silicon layers 8 can modified to yield, after processing to trim the silicon and form a capping layer 24 thereover, final wires 58a-58c having the same or substantially the same thicknesses. Likewise, the thicknesses of the silicon germanium layers are modified as a result of the changes in the thickness of the silicon layers, and to yield uniform or substantially uniform spacing between adjacent final wires 58a-58c and between final wire 58c and the facing surface of the capping layer 24 on the substrate 2. By measuring the different ones of the final wires 58a-58d in FIG. 2d and the thicknesses of the capping layer 24 on each of those final wires 58a-58c, a change in the thickness of the silicon layers 8 which will result in uniform or more uniform thickness final wires 58a-58c is determined. This assumes that the change in the thickness in the Y-direction of any one of the silicon layers 8 in the superlattice results in an equal change in the thickness in the Y-direction on the post trim wire preforms 52′-56′, and that using the same trim and capping layer deposition process conditions will result in similar trim and capping layer characteristics to those shown in FIGS. 2c and 2d. Then, based on the assumed thickness of the post trim wire preforms 52′-56′ and the capping layer 24 thereover, and of the capping layer on the etched or trimmed surface of the substrate 2, the relative location of each of the silicon layers 8 with respect to the upper surface of the substrate 2 to yield equal spacing of the final wires 58a-58c and between final wire 58c and the facing surface of the capping layer 24 on the substrate 2 can be determined. In this determination, it is assumed that the thickness of the capping layer 24 formed on the trimmed wire preforms 52-56′ and on the upper surface of the substrate 2 will be substantially unchanged as compared to the result in FIG. 2d. Thus, a desired final thickness of each of the final wires 58a-58c can be selected, and the spacing between the wire preforms 52-56 likewise chosen. Then, the thickness of the post trim wire preforms required in each of the final wires 58a-58c is determined arithmetically based on the presumed thickness of the capping layer 24 thereon. The difference between this desired thickness and the actual thickness of the post trim wire preforms 52′ to 56 is then determined. If the thickness of the post trim wire preform 52′-56′ is less than the new desired thickness, then the difference between this actual thickness of FIG. 2d and the desired thickness is added to the thickness of the silicon layer 8 in the superlattice from which the post trim wire preform in question is formed. Likewise, if the desired thickness is less than the thickness of the post-trim wire preform 52′-56′ of FIG. 2d, the thickness of that silicon layer 8 is reduced in the superlattice. Then, the thicknesses of the silicon germanium layers 6 in the superlattice required to result in uniform spacings between the final wires 58a-58 c and between final wire 58c and the capping layer on the substrate 2 are determined.

To determine the thicknesses of the different silicon germanium layers 6 in the superlattice, the location of the centers, in the Y direction, of each of the modified post trim wire preforms 52′ to 56′ in the equally spaced final wires 58a-58c as shown in FIG. 3d can be used as the center, in the Y direction, of the silicon layer 8 of the superlattice corresponding thereto. Then, based on the new thicknesses of the modified thickness silicon layers 8 of FIG. 3c and the center of each of them in the Y-direction, the thickness of the silicon germanium layers 6 required to properly locate them relative to the substrate can be calculated, and these thicknesses of the silicon germanium layers 6 used to form the superlattice. Again, in determining the location of the trimmed wire preforms 52′-56′ to yield equal spacing of the final wires 58a-c, it is assumed that the amount of silicon removed from the wire preforms 52-56 is substantially the same as was removed in the example on FIG. 2a-2d hereof, and the thickness of the capping layers 24 on the different ones of the post trim wire preforms 52′-56′ will be that same as that in the example on FIG. 2a-2d hereof. Here, the thickness of the superlattice of the fin or mesa 10 of FIGS. 2a and 3 are the same, within design tolerance.

In one aspect hereof, to determine the desired thicknesses of the modified thickness silicon layers 8 in FIG. 3a, an average value of the thicknesses T1 to T3 of the first to third final wires 58a to 58c of FIG. 2a can calculated. The thicknesses of the silicon layers 8 in the superlattice can then be modified using this information. As a result, a silicon layer 8 corresponding to a thicker than the average thickness of the final wires 58a-58c of FIG. 2d is made smaller, and a silicon layer 8 corresponding to a thinner than the average thickness of the final wires 58a-58c of FIG. 2d is made thicker. Alternatively, a mean value of the thickness, or other paradigm, may be used to resize the thicknesses of the silicon layers 8 in the superlattice from the equal thicknesses thereof in FIG. 2d. Where the mean value of the thicknesses T1 to T3 is used, the silicon layers 8 corresponding to a final wire thicker than the mean of the thicknesses T1 to T3 in FIG. 2b are modified so that those having a corresponding final wire 58 with a thickness greater than the mean will be modified to be thinner than those having a corresponding final wire 58 with a thickness less than the mean value. Using this methodology, a minimum design thickness of the post trim wire preform 52′-56′ must be respected.

Using a mean or average value of the thicknesses of the first to third final wires 58a to 58c incorporates two different variations of thickness into the average or mean values: The variation in the thicknesses t2a′ to t2c′ of the first to third post trim wire preforms 52, 54 and 56, and the variation in the thicknesses d1 to d3 of the second silicon germanium layers 24. An additional paradigm for changing the dimensions of the silicon layers 8 in the superlattice is to determine the average or mean value of the thicknesses d1 to d3 of only the second silicon germanium layers 24 of FIG. 2d. The difference between that average (or mean) thickness is used to modify the thickness of the silicon layer 8 of the superlattice corresponding to a specific one of the first to third final wires 58.

The differences in the spacings s1a′, s1b′ and s1c′ of the resulting structure of FIG. 2d can also be used to determine a change value for the thicknesses of the silicon layers 8 of or in the superlattice. The differences in the spacings reflect the inverse of the of the changes of the thicknesses of the first to third final wires 58a-to 58c, and can thus be used in the same way as are the differences in the thicknesses of the first to third final wires 58a to 58c to determine a change in the thickness of the silicon layers from those in FIG. 2a to those in FIG. 3a.

As the uppermost silicon layer 8 in the fin or mesa 10 of FIG. 2a resulted in a first final wire 58a of the greatest thickness, the thickness t2a of the uppermost silicon layer of FIG. 3a is reduced in size as compared to that silicon layer 8 in FIG. 2a using one of the change paradigms discussed herein. The thickness t2b of the middle silicon layer 8 in the fin or mesa 10 of FIG. 3a, which resulted in a second final wire 58b FIG. 2d having an intermediate thickness as among the three first to third final wires 58a to 58c may change based on one of the paradigms discussed herein. Here, the thickness t1b is approximately the same thickness as corresponding silicon layer 8 of FIG. 2a. The lowermost silicon layer of the fin or mesa 10 of FIG. 3a, which resulted in a third final wire 58c of FIG. 2d having the smallest thickness as among the first to third final wires 58a to 58c is increased as compared to the corresponding silicon layer 8 of FIG. 2a, for example using a paradigm described herein. As a result, in comparing the thicknesses of the silicon layers 8 of FIGS. 2a and 3a, t1a>t2a, t1b=t2b, and t1c<t2c, and t2c>t2b>t2a. Here, preferably the same paradigm of change is used to set the thicknesses of all of the silicon layers 8 in the superlattice where a greater or lesser number of silicon layers 8 is provided. With a known change in the thicknesses of the silicon layers 8 in the stack, the corresponding changes in the thicknesses of the silicon germanium layers 6 are determined. The difference in the thickness of the silicon germanium layers can be determined by changing the thickness of the silicon germanium layer by one-half of the change in each of the silicon layers adjacent thereto

Additionally, to achieve greater uniformity final wire 58 spacing and final wire 58 thickness, the relative sizes of the silicon layers in the superlattice can be simply increased or decreased based on the resulting dimensions of the structure of FIG. 2d. By using the same device structure but varying the thicknesses of the initial silicon 8 and silicon germanium 6 layers, removing the silicon germanium layers, trimming the silicon layers 8, and then forming the capping layer of silicon germanium on the trimmed silicon layer 8, the resulting uniformity or non-uniformity can be determined, such as by measurement thereof using a TEM or SEM to image a sectioned structure as shown in FIG. 2d or 3d. Then, if the uniformity is acceptable, the new thicknesses of the silicon 8 and silicon germanium layers 6 are used to form the HGAA device. If the non-uniformity of the final wire 58 spacing, the final wire 58 thickness, or both are inadequate, new dimensions can be selected for the silicon layers 8 and silicon germanium layers 6 can be selected, and the superlattice processed again as shown in FIG. 3a to 3d, and again the thicknesses and spacings of the final wires 58 evaluate. Using multiple iterations, if required, of the relative thicknesses of the silicon and silicon germanium layer, a final thickness for the silicon layers 8, and thus for the silicon germanium layers 6, can be ascertained.

As described with respect to FIG. 2a, the thickness of the epitaxially grown silicon germanium capping layer 24 is inherently thinner over the trimmed wire preform 56c′ closest to the substrate 2 (and thus deeper in the trench 11), as compared to that formed on the first post trim wire preform 52′ furthest from the substrate 2. Thus here the third silicon layer 8 closest to the substrate 2 is, after etching to trim that silicon layer 8, thicker than the trimmed first silicon layer 8 furthest from the substrate 2. Using the measured thicknesses of the first to third post trim wire preforms 52′ to 56′ and of the second silicon germanium layers 24 of FIG. 2d, and determining the differences between the measured thicknesses and the desired thicknesses of the final wires 58 in the Y direction, the resulting changes in thickness, if any, of each of the silicon layers 8 is determined. For example, if the spacing between any of the first to third final wires 58a to 58c or a third final wire 58c and the substrate 2 is too small, the thickness of the first silicon germanium layer therebetween can be increased, and the thickness of one or both of the silicon layers 8 thereadjacent may be reduced. Additionally, to form final wires 58 having equal thicknesses over the substrate 2, the silicon layer thickness can be increased where the finished wire formed therefrom is smaller in thickness than the final wires 58 formed from other silicon layers 8. Here, for example, an increase in thickness of the lower (closer to the substrate 2) silicon layers 8 can be calculated, assuming that the thicknesses of the silicon germanium layers will change approximately the same in the depth direction of the trench between adjacent fins 10 when deposited on different thickness silicon layers as they changed in FIG. 2d. Thus, an estimation of the desired thickness of each of the silicon layers 8 of the superlattice, and the corresponding silicon germanium layers therebetween (and between the silicon layer closest to the substrate 2 and the facing surface of the substrate 2) is calculated. The superlattice is formed having these different thickness silicon germanium layers 6 and silicon layers 8 in the depth direction of the superlattice (thinner silicon layers 8 furthest from the substrate 2 and thicker silicon layers closer to the substrate 2). To maintain the desired position of the surface of the superlattice farthest from the substrate 2 relative to the facing surface of the substrate, the thicknesses of the silicon germanium layers will also change in the depth direction of the trench 11 (and of the superlattice), with thicker silicon germanium layers 6 further form the substrate 2 and thinner silicon germanium layers closer to the substrate 2. As a result of this construct, after the selective removal of the silicon germanium layer 6, the trimming of the resulting first to third wire preforms 52-56, and the deposition of the second silicon germanium layers as a capping layer 24 onto the first to third post trim wire preforms 52′-56′, the spacings s2a′, s2b′ between the adjacent finished wires 58a and 58b, and the spacing between the third finished wire 58c and the facing surface of the substrate 2 are more uniform as shown in FIG. 3d as compared to FIG. 2d.

In the event that the resulting uniformity of the spacings s2a′, s2b′ between the adjacent finished wires 58a and 58b, and the spacing s2c′ between the third finished wire 58c and the facing surface of the capping layer 24 on the substrate 2 are not sufficiently uniform, the process of measuring the resulting dimensions of the new or just formed set of the first to third final wires 58a, 58b and 58c of the new or just formed structure is performed, and new thicknesses of the silicon layers in the superlattice stack to provide more uniform thicknesses of the finished wires 58a to 58c and the spacings s2a′, s2b′ and s2c′ are determined. Thus, for a given horizontal gate all around structure, the thicknesses of the silicon layers 8 and the first silicon germanium layers 6 which will result in uniform spacings for the spacings s2a′, s2b′ and s2c′ and more uniform finished wire thicknesses 58a to 58c can be iteratively determined and implemented in an intermediate preform of the HGAA device.

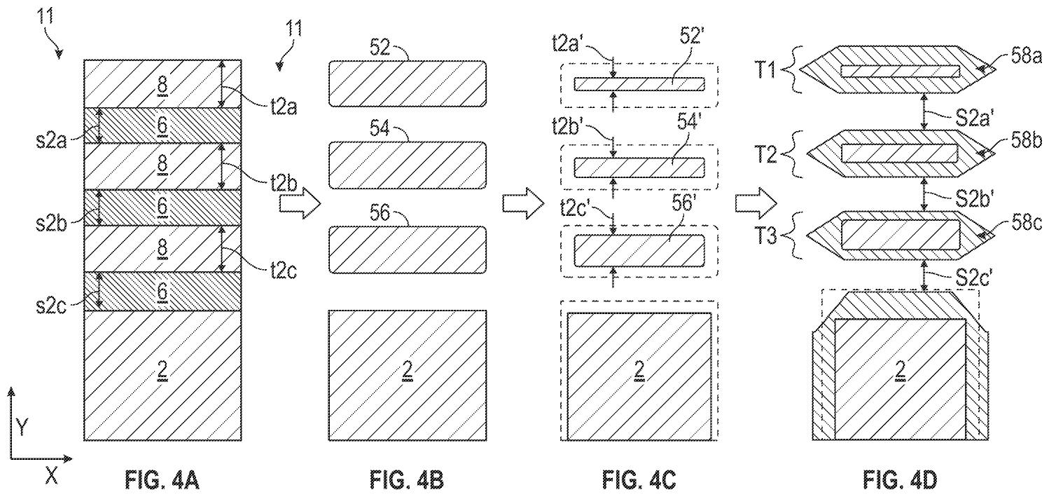

Referring now to FIGS. 4a to 4d, a further approach to reduce the variation in spacing between adjacent finished wires 58a-58c and finished wire 58c and the substrate 2 in a horizontal gate all around structure is shown schematically. Here, the individual silicon germanium layers 6 and silicon layers 8 are grown or formed to the same thickness as those of FIG. 2a, i.e., t2a=t2b=t2c, but the properties of the trim process are changed to modify the variation of the thickness of the first to third post trim wire preforms 52′-56′ in the depth direction of the trench 11. For example, by reducing the pressure in the processing chamber where the remote plasma etch process is being performed as compared to that resulting in the first to third post trim wire preforms 52 to 56 of FIG. 2c, where the relative concentration of the gases used in the trim process is not changed, the quantity of the first post trim wire preform 52′ furthest from the substrate 2 that is etched away is greater than that removed from the second post trim wire preform 54′, which quantity is itself greater than the amount of material removed or etched from the third post trim wire preform 56′ closest to the substrate 2. Here, the process time to form the trimming may be extended as compared to the process time employed to form the post trim wire preforms 52′-56′ of FIG. 2c. As a result, where the same thickness of the capping layer 24 as that in FIG. 2d is deposited thereover, the spacings s1-s3 between the first to third final wires 58a to 58 c and between the lowermost third final wire 58c and the facing surface of the capping layer 24 on the substrate 2 are more uniform, although the silicon layers 8, and thus the first to third wire preforms 52-56, all have the same thickness and spacings from one another within deposition and design tolerances. Here, by adjusting the deposition parameters as described, the thickness t2a′ of the first post trim wire preform 52′ is less than the thickness t2b′ of the second post trim wire preform 54′. Likewise the thickness t2b′ of the second post trim wire preform 54′ is less than the thickness t2c′ of the third post trim wire preform 56′. In other words, by varying the process parameters used to trim the silicon layer 8, and using the same silicon layer and silicon germanium layer 6 thicknesses as that used in the superlattice of FIG. 2a, different thicknesses of the silicon layers 8 after trimming can be achieved as compared to those in FIG. 2c. Here, by adjusting those parameters, the thicknesses of the post trimmed wire preforms follow the paradigm of t2c′>t2b′>t2a′. By depositing the capping layer 24 of, for example, silicon germanium over the first through third post trim wire preforms 52′ to 56′ and the exposed surface of the substrate 2, because the capping layers 24 deposited on first to third post trim wire preforms 52′ to 56′ have different thicknesses with respect to each other on the different ones of the first to third post trim wire preforms 52′ to 56′ as discussed herein with respect to FIG. 2d, the spacings s1a′, s1b′ and s1c′ between the final wires 58a-58 d will be more uniform in thickness than spacings where the same relative thicknesses of the capping layer 24 were formed using the processes described with respect to FIG. 2d.

The desired relative thicknesses of the first to third post trim wire preforms 52′ to 56′ of FIG. 4c can be determined using the same change paradigms as discussed with respect to the process of described with respect to FIGS. 3a-3c. The difference here is that the difference in the desired thickness is applied to form the first to third post trim wire preform 52′ to 56′, and not in forming the original silicon layer 8. Here, preferably, the non-uniform thicknesses T1, T2 and T3 of the first to third final wires 58a, 58b and 58c, such as those of FIG. 2d are used to determine the desired thicknesses of the first to third post trim wire preforms 52′, 54′ and 56′. Because the same superlattice stack of FIG. 2a is employed, the positions of the individual first to third wire preforms 52′, 54′ and 56′ are preset by the thicknesses of the first silicon germanium layers 6. Here, the etching to trim the first to third wire preforms 52-56 is isotropic, or primarily so, such that an nearly equal thickness of silicon will be removed uniformly over the exposed outer surfaces of an individual first to third wire preforms 52-56, although different thicknesses will inherently be etched away on different ones of the wire preforms 52, 54, 56 at their different distances from the upper surface of the substrate 2.

One may simply increase or decrease the relative thicknesses of the first to third post wire preforms 52′ to 56′, and the relative thicknesses of the capping layers 24 thereon, to experimentally and iteratively achieve an acceptable result in terms of the difference in thickness in the Y-direction of the final wires 58 to 58c. However, a first approximation to help determine these thicknesses can be approached arithmetically. Here, the thicknesses t1a′, t1b′ and t1c′ of each of the first to third post trim wire preforms 52′ to 56′ of FIG. 2d are measured, as are the total thicknesses T1, T2 and T3 of each of the finished wires 58a to 58c of FIG. 2d. An average of the thicknesses T1, T2 and T3 is arithmetically determined as Tave=(T1+T2+T3)/3. Where subtracting the Tave from a given finished wire thickness is a positive number, that value of that positive number is subtracted from the desired post trim wire thickness of that finished wire to provide a target post trimmed wire thickness. Where subtracting the Tave from a given finished wire thickness is a negative number, the value of that negative number is added to the desired post trim wire thickness of that finished wire to provide a target post trimmed wire thickness. The intent here is to provide a target thickness for the thickness of the post trim wire preforms 52′-56′ based on the differences in the thickness of the final wires 58a-58c in which they reside. Then, using the same etch chemistry and remote plasma approach used to trim the wire preforms 52-56 of FIG. 2d, and by varying the process parameters of the trim process, for example the process pressure, the targeted or desired post trim wire preform 52′ to 56′ thicknesses can be achieved. By simple iteration of process runs at different process parameters and trim etch concentrations, a sufficiently close to the desired post trim wire preform 52′ to 56′ thicknesses, and relative thicknesses between those post trimmed wire preforms 52′ to 56′, can be achieved.

For example, as shown in FIG. 2d, first final wire 58a is thicker than both the second and third final wires 58b and 58c, and this is thicker than the average final wire 58 thickness. Thus the difference between the final wire thickness T1 of FIG. 2d and Tave is subtracted from the thickness t1a′ of the first post trim wire preform 52′ to yield a target thickness Tₜₐᵣ for that first post trim wire preform 52′. Likewise, as shown in FIG. 2d, third final wire 58c is thicker than both of first and second final wires 58a and 58b, and thus is thinner than the average finished wire 58 thickness. Thus the difference between the third final wire 58c thickness T3 of FIG. 2d and Tave is added to the thickness t1c′ of the post trim wire preform 56′ to yield a target thickness Tₜₐᵣ for post wire preform 56′. Similarly, the difference between T2 and Tave is used to adjust the thickness of trimmed wire preform 54′, if there is a difference between those values. Thus, by changing the etch properties of the trimming process to yield the Tₜₐᵣ for each wire preform, after the capping layer 24 is formed thereover, the resulting final wires 58a to 58c will have equal thicknesses, or nearly equal thickness values, in the Y-direction. Thus the spacings between the finished wires 58a to 58c and between finished wire 58c and the facing surface of the capping layer 24 formed on the substrate will have the same, or nearly the same, span or gap values.

If the resulting spacings 32a′, s2b′ and 52c′ and final wire thicknesses T1-T3 are not sufficiently uniform, the etch process for trimming the wire preforms 52-56, may again be modified to iteratively reach the desired uniformity.

FIG. 5 is a schematic top-view diagram of an example of a multi-chamber processing system 100 useful to form the individual semiconductor layers and capping layers according to some examples of the present disclosure. The processing system 100 generally includes a factory interface 102, load lock chambers 104, 106, transfer chambers 108, 116 with respective transfer robots 110, 118, holding chambers 112, 114, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers in a low pressure (e.g., less than or equal to about 300 Torr) or vacuum environment without breaking the low pressure or vacuum environment between various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, Calif. It is contemplated that other processing systems (including those from other manufacturers) may be adapted to benefit from aspects described herein.

In the illustrated example of FIG. 5, the factory interface 102 includes a docking station 140 and factory interface robots 142 to facilitate transfer of substrates. The docking station 140 is configured to accept one or more front opening unified pods (FOUPs) 144. In some examples, each factory interface robot 142 generally comprises a blade 148 disposed on one end of the respective factory interface robot 142 configured to transfer the substrates from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 112, 114 and respective ports 162, 164 coupled to processing chambers 120, 122. Similarly, the transfer chamber 116 has respective ports 166, 168 coupled to the holding chambers 112, 114 and respective ports 170, 172, 174, 176 coupled to processing chambers 124, 126, 128, 130. The ports 154, 156, 158, 160, 162,164, 166, 168, 170, 172, 174, 176 can be, for example, slit valve openings with slit valves for passing substrates therethrough by the transfer robots 110, 118 and for providing a seal between respective chambers to prevent a gas from passing between the respective chambers. Generally, any port is open for transferring a substrate therethrough; otherwise, the port is closed.

The load lock chambers 104, 106, transfer chambers 108, 116, holding chambers 112, 114, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps, etc.), gas sources, various valves, and conduits fluidly coupled to the various chambers. In operation, a factory interface robot 142 transfers a substrate from a FOUP 144 through a port 150 or 152 to a load lock chamber 104 or 106. The gas and pressure control system then pumps down the load lock chamber 104 or 106. The gas and pressure control system further maintains the transfer chambers 108, 116 and holding chambers 112, 114 with an interior low pressure or vacuum environment (which may include an inert gas). Hence, the pumping down of the load lock chamber 104 or 106 facilitates passing the substrate between e.g., the atmospheric environment of the factory interface 102 and the low pressure or vacuum environment of the transfer chamber 108.

With the substrate in the load lock chamber 104 or 106 that has been pumped down, the transfer robot 110 transfers the substrate from the load lock chamber 104 or 106 into the transfer chamber 108 through the port 154 or 156. The transfer robot 110 is then capable of transferring the substrate to and/or between any of the processing chambers 120, 122 through the respective ports 162, 164 for processing and the holding chambers 112, 114 through the respective ports 158, 160 for holding to await further transfer. Similarly, the transfer robot 118 is capable of accessing the substrate in the holding chamber 112 or 114 through the port 166 or 168 and is capable of transferring the substrate to and/or between any of the processing chambers 124, 126, 128, 130 through the respective ports 170, 172, 174, 176 for processing and the holding chambers 112, 114 through the respective ports 166, 168 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 122 can be capable of performing a cleaning process; the processing chamber 120 can be capable of performing an etch process; and the processing chambers 124, 126, 128, 130 can be capable of performing respective epitaxial growth processes. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif.

A system controller 190 is coupled to the processing system 100 for controlling the processing system 100 or components thereof. For example, the system controller 190 may control the operation of the processing system 100 using a direct control of the chambers 104, 106, 108, 112, 114, 116, 120, 122, 124, 126, 128, 130 of the processing system 100 or by controlling controllers associated with the chambers 104, 106, 108, 112, 114, 116, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, e.g., a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 116 and the holding chambers 112, 114. In other examples, more or fewer transfer chambers (e.g., one transfer chamber) and/or more or fewer holding chambers (e.g., no holding chambers) may be implemented as a transfer apparatus in a processing system.

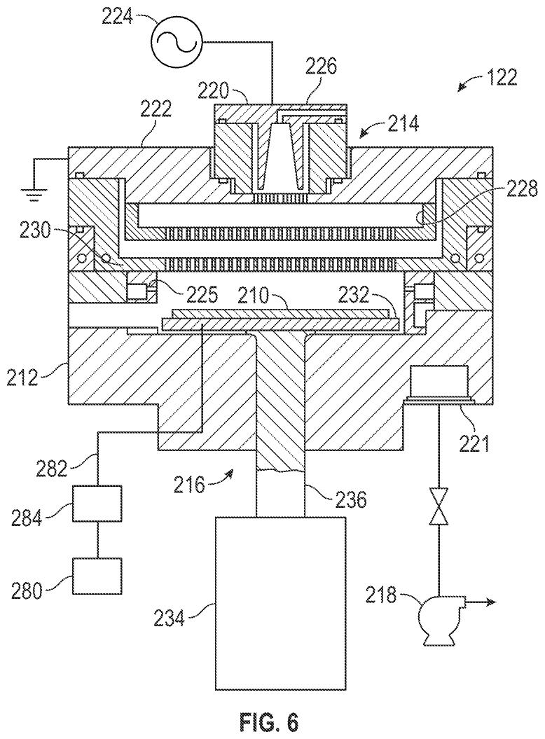

FIG. 6 is a cross-sectional view of a processing chamber 122 that may be used to perform a cleaning process. The processing chamber 122 may be a SiCoNi® Preclean chamber available from Applied Materials of Santa Clara, Calif. The processing chamber 122 includes a chamber body 212, a lid assembly 214, and a support assembly 216. The lid assembly 214 is disposed at an upper end of the chamber body 212, and the support assembly 216 is at least partially disposed within the chamber body 212. The chamber body 212, lid assembly 214, and support assembly 216 together define a region in which a substrate may be processed.

The lid assembly 214 includes at least two stacked components configured to form a plasma region therebetween. A first electrode 220 is disposed vertically above a second electrode 222 confining a plasma volume therebetween. The first electrode 220 is connected to a radio frequency (RF) power source 224, and the second electrode 222 is connected to ground, which forms a capacitance between the first electrode 220 and the second electrode 222.

The lid assembly 214 also includes one or more gas inlets 226 for providing a cleaning gas to a substrate surface through a blocker plate 228 and a gas distribution plate 230, such as a showerhead. The cleaning gas may be an etchant, ionized gas or active radical, such as ionized fluorine, chlorine, or ammonia. In other examples, a different cleaning process may be utilized to clean the substrate surface. For example, a remote plasma containing He and NF3 may be introduced into the processing chamber 122 through the gas distribution plate 230, while NH3 may be directly injected into the processing chamber 122 via a separate gas inlet 225 that is disposed at a side of the chamber body 212.

The support assembly 216 may include a substrate support 232 to support a substrate 210 thereon during processing. The substrate support 232 has a flat substrate supporting surface for supporting the substrate to be processed thereon. The substrate support 232 may be coupled to an actuator 234 by a shaft 236 which extends through a centrally-located opening formed in a bottom of the chamber body 212. The actuator 234 may be flexibly sealed to the chamber body 212 by bellows (not shown) that prevent vacuum leakage from around the shaft 236. The actuator 234 allows the substrate support 232 to be moved vertically within the chamber body 212 between a process position and a lower, transfer position. The transfer position is slightly below the opening of a slit valve opening formed in a sidewall of the chamber body 212. In operation, the substrate support 232 may be elevated to a position in close proximity to the lid assembly 214 to control the temperature of the substrate 210 being processed. As such, the substrate 210 may be heated via radiation emitted or convection from the gas distribution plate 230.

A bias RF power supply 280 may be coupled to the substrate support 232 through a matching network 284. The bias RF power supply 280 provides a bias to the substrate 210 to direct the ionized cleaning gas toward the substrate 210.

A vacuum system, which may be part of the gas and pressure control system of the processing system 100, can be used to remove gases from the processing chamber 122. The vacuum system includes a vacuum pump 218 coupled to a vacuum port 221 disposed in the chamber body 212. The processing chamber 122 also includes a controller (not shown), which may be the system controller 190 or a controller controlled by the system controller 190, for controlling processes within the processing chamber 122.

FIG. 7 is a cross-sectional view of a processing chamber 120 that may be used to perform a selective etch process and trimming process. The processing chamber 120 may be a Selectra® Etch chamber available from Applied Materials of Santa Clara, Calif. The processing chamber 120 includes a chamber body 302, a lid assembly 304, and a support assembly 306. The lid assembly 304 is disposed at an upper end of the chamber body 302, and the support assembly 306 is at least partially disposed within the chamber body 302. The chamber body 302, lid assembly 304, and support assembly 306 together define a region in which a substrate may be processed. As apparent from the following description, the processing chamber 120 may implement one or more capacitively coupled plasmas (CCPs).

The lid assembly 304 includes an RF electrode 308. A gas inlet tube 310 extends through the RF electrode 308 and is further coupled to a gas manifold 312. A flow centering insert 314 can be disposed in the gas inlet tube 310. A gas source 316 is fluidly coupled to the gas inlet tube 310 via the gas manifold 312. The gas source 316 can provide a flow 318 of gas through the gas inlet tube 310, and further, through the flow centering insert 314. An RF power source 320 and RF matching network 322 are coupled to the RF electrode 308 and, hence, also to the gas inlet tube 310.

A blocker plate 324 is coupled to the RF electrode 308 and may be maintained at a same electrical potential as the RF electrode 308. The blocker plate 324 has apertures therethrough that permit gas to flow through the blocker plate 324. A gas distribution plate 326 is likewise coupled to the RF electrode 308 and may be maintained at a same electrical potential as the RF electrode 308. The gas distribution plate 326 is more distal from the RF electrode 308 than the blocker plate 324. The gas distribution plate 326 also has apertures therethrough that permit gas to flow through the gas distribution plate 326. The blocker plate 324 and gas distribution plate 326 can serve to redirect a flow of gas so that gas flow is more uniform on respective sides of the blocker plate 324 and gas distribution plate 326 opposite from the source of the gas in the chamber 120 (e.g., the gas inlet tube 310).

An insulator 330 separates and electrically insulates the gas distribution plate 326 from a gas distribution device 334. The gas distribution device 334 is grounded. The gas distribution device 334 is grounded and has apertures therethrough. Surfaces of the gas distribution plate 326, the gas distribution device 334, and the insulator 330 define a first plasma region 332 (e.g., a remote plasma region). A plasma may be generated in the first plasma region 332 when a flow 318 of gas is provided through the gas inlet tube 310, which passes through the blocker plate 324 and the gas distribution plate 326, and RF energy is provided by the RF power source 320 through the RF electrode 308 and the gas distribution plate 326. Plasma products (e.g., radicals, ions, and electrons) may pass through the gas distribution device 334 when a plasma is generated in the first plasma region 332. In general, the position of the grounded gas distribution device 334 between the gas distribution plate 326 and the process region 352 minimizes or prevents gases ionized in the plasma formed above the gas distribution device 334 from reaching the surface of the substrate during processing. The reduced exposure to an ion containing processing gas prevents or minimizes the amount of damage induced in the substrate due to the bombardment of the surface of the substrate by the plasma generated ions.

The gas distribution device 334 further has channels 336 fluidly coupled to a gas source 338 that may be used to introduce one or more additional gas on a side of the gas distribution device 334 distal from the first plasma region 332. The gas source 338 can provide a flow 340 of gas through the channels 336. A heating element 342 may be disposed in the gas distribution device 334 or other components and may facilitate a thermal distribution and maintenance of a plasma in the first plasma region 332.

The support assembly 306 includes a substrate support 348 supported by the chamber body 302. The support assembly 306 is configured to support a substrate 350. A second plasma region (e.g., a direct plasma region) is defined in a process region 352 between the gas distribution device 334 and the substrate 350. The gases from flow 318 and plasma products from the first plasma region 332 can pass through the gas distribution device 334 into the process region 352. The substrate support 348 is further connected to a RF power source 354 to provide a bias during processing. A plasma may be generated in the second plasma region in the process region 352 when a flow 340 of gas is provided through the channels 336 of the gas distribution device 334 and an RF energy is provided by the RF power source 354 to the substrate support 348.

The support assembly 306 can include an electrostatic chuck (ESC). The substrate support 348 may be coupled to an actuator 356 by a shaft 358 which extends through a centrally-located opening formed in a bottom of the chamber body 302. The actuator 356 may be flexibly sealed to the chamber body 302 by bellows (not shown) that prevent vacuum leakage from around the shaft 358. The actuator 356 allows the substrate support 348 to be moved vertically within the chamber body 302 between a process position and a lower, transfer position. The transfer position is slightly below a slit valve opening (not shown) formed in a sidewall of the chamber body 302. In operation, the substrate support 348 may be elevated to a position in close proximity to the lid assembly 304. Although not specifically illustrated, the substrate support 348 can include a heating element and cooling element to maintain the substrate 350 at a target temperature during processing.

A vacuum system, which may be part of the gas and pressure control system of the processing system 100, can be used to remove gases from the processing chamber 120. The vacuum system includes a vacuum pump 362 coupled to a vacuum port 364 disposed in the chamber body 302.

The processing chamber 120 also includes a controller (not shown), which may be the system controller 190 or a controller controlled by the system controller 190, for controlling processes within the processing chamber 120.

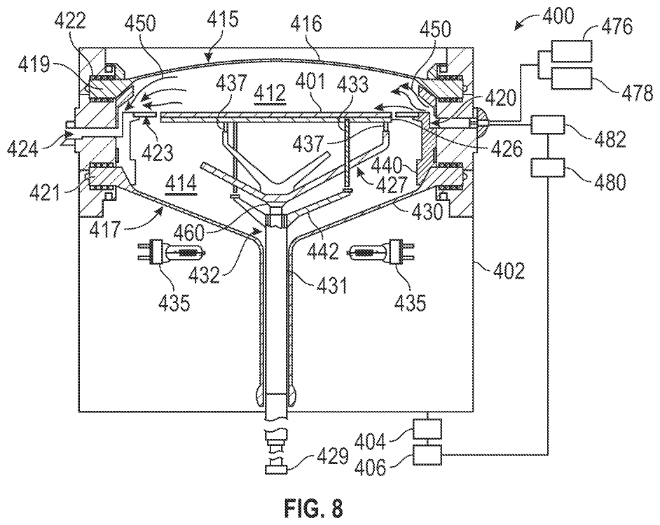

FIG. 8 is a cross-sectional view of a thermal processing chamber 400 that may be used to perform epitaxial growth. The processing chamber 400 includes a chamber body 402, support systems 404, and a controller 406. The chamber body 402 includes an upper portion 412 and a lower portion 414. The upper portion 412 includes the area within the chamber body 402 between an upper dome 416 and a substrate 401. The lower portion 414 includes the area within the chamber body 402 between a lower dome 430 and the bottom of the substrate 401. Deposition processes generally occur on the upper surface of the substrate 401 within the upper portion 412.

The support system 404 includes components used to execute and monitor pre-determined processes, such as the growth of epitaxial films in the processing chamber 400. A controller 406 is coupled to the support system 404 and is adapted to control the processing chamber 400 and support system 404. The controller 406 may be the system controller 190 or a controller controlled by the system controller 190 for controlling processes within the processing chamber 400.

The processing chamber 400 includes a plurality of heat sources, such as lamps 435, which are adapted to provide thermal energy to components positioned within the process chamber 400. For example, the lamps 435 may be adapted to provide thermal energy to the substrate 401, a susceptor 426, and/or the preheat ring 423. The lower dome 430 may be formed from an optically transparent material, such as quartz, to facilitate the passage of thermal radiation therethrough. It is contemplated that lamps 435 may be positioned to provide thermal energy through the upper dome 416 as well as the lower dome 430.

The chamber body 402 includes a plurality of plenums formed therein. The plenums are in fluid communication with one or more gas sources 476, such as a carrier gas, and one or more precursor sources 478, such as deposition gases and dopant gases. For example, a first plenum 420 may be adapted to provide a deposition gas 450 therethrough into the upper portion 412 of the chamber body 402, while a second plenum 424 may be adapted to exhaust the deposition gas 450 from the upper portion 412. In such a manner, the deposition gas 450 may flow parallel to an upper surface of the substrate 401.

In cases where a liquid precursor is used, the thermal processing chamber 400 may include a liquid vaporizer 480 in fluid communication with a liquid precursor source 482. The liquid vaporizer 480 is be used for vaporizing liquid precursors to be delivered to the thermal processing chamber 400. While not shown, it is contemplated that the liquid precursor source 482 may include, for example, one or more ampules of precursor liquid and solvent liquid, a shut-off valve, and a liquid flow meter (LFM).

A substrate support assembly 432 is positioned in the lower portion 414 of the chamber body 402. The substrate support assembly 432 is illustrated supporting a substrate 401 in a processing position. The substrate support assembly 432 includes a susceptor support shaft 427 formed from an optically transparent material and the susceptor 426 supported by the susceptor support shaft 427. A shaft 460 of the susceptor support shaft 427 is positioned within a shroud 431 to which lift pin contacts 442 are coupled. The susceptor support shaft 427 is rotatable in order to facilitate the rotation of the substrate 401 during processing. Rotation of the susceptor support shaft 427 is facilitated by an actuator 429 coupled to the susceptor support shaft 427. The shroud 431 is generally fixed in position, and therefore, does not rotate during processing. Support pins 437 couple the susceptor support shaft 427 to the susceptor 426.

Lift pins 433 are disposed through openings (not labeled) formed in the susceptor support shaft 427. The lift pins 433 are vertically actuatable and are adapted to contact the underside of the substrate 401 to lift the substrate 401 from a processing position (as shown) to a substrate removal position.

The preheat ring 423 is removably disposed on a lower liner 440 that is coupled to the chamber body 402. The preheat ring 423 is disposed around the internal volume of the chamber body 402 and circumscribes the substrate 401 while the substrate 401 is in a processing position. The preheat ring 423 facilitates preheating of a process gas as the process gas enters the chamber body 402 through the first plenum 420 adjacent to the preheat ring 423.

The central window portion 415 of the upper dome 416 and the bottom portion 417 of the lower dome 430 may be formed from an optically transparent material such as quartz. The peripheral flange 419 of the upper dome 416, which engages the central window portion 415 around a circumference of the central window portion 415, the peripheral flange 421 of the lower dome 430, which engages the bottom portion around a circumference of the bottom portion, may all be formed from an opaque quartz to protect the O-rings 422 proximity to the peripheral flanges from being directly exposed to the heat radiation. The peripheral flange 419 may be formed of an optically transparent material such as quartz.

As discussed previously, the hGAA structure uses a plurality of semiconductor layers, stacked one over the other, and extending between a source and a drain region of a substrate. To form the structure, a superlattice, individual semiconductor layers, for example semiconductor sheet layers are sequentially deposited or formed using an epitaxial deposition process, with sacrificial layers alternately deposited or formed between each of the semiconductor layers. In one aspect, the semiconductor layer is single crystal silicon, for example doped single crystal silicon, and the sacrificial layers are silicon germanium layers. This process results in a stack of silicon and silicon germanium layers, which are then singulated into individual fins or mesas of superlattice extending between what will be source and drain regions of a device.

While the foregoing is directed to various examples of the present disclosure, other and further examples may be devised without departing from the basic scope thereof, and the scope thereof is determined by the claims that follow

What is claimed is:

1. A method of forming a semiconductor device, comprising:
forming a first superlattice on a first substrate, the first superlattice comprising alternating sub-layers of a first material comprising a semiconductor and sub-layers of a second material, wherein the thicknesses of the first material sub-layers are a first thicknesses and the thicknesses of the second material sub-layers are a second thickness, wherein at least a first sub layer of the first material and a second sub layer of the first material are formed in the first superlattice, the second sublayer of the first material interposed between the first sublayer of the first material and the substrate;
removing the sub-layers of the second material from the first superlattice;
etching the first and second sub-layers of the first material of the first superlattice to remove a portion of the first material thereof and form a first trimmed sub-layer of the first material and a second trimmed sub-layer of the first material, wherein the amount of first material removed from the first sub-layer of the first material is greater than the amount of material removed from the second sub-layer of the first material; and
depositing a capping layer over the first trimmed sub-layer of the first material of the first superlattice, over the second trimmed sub-layer of the first material of the first superlattice, and on an exposed surface of the substrate;
measuring the distance between the capping layer on the first sub-layer and the capping layer on the second sublayer, and the distance between the capping layer on the second sub-layer and the capping layer on the substrate, and determining a first difference between those distances;
forming a second superlattice on a second substrate, the second superlattice comprising alternating sub-layers of the first material comprising a semiconductor and sub-layers of the second material, wherein the thicknesses of the first material sub-layers are a first thicknesses and the thicknesses of the second material sub-layers are a second thickness, wherein at least a first sub layer of the first material and a second sub layer of the first material are formed in the second superlattice, the second sublayer of the first material interposed between the first sublayer of the first material and the second substrate;
removing the sub-layers of the second material from the second superlattice and the second substrate;
etching the first and second sub-layers of the first material of the second superlattice to remove a portion of the first material thereof and form a first trimmed sub-layer of the first material and a second trimmed sub-layer of the first material, wherein the process conditions used to remove the portions of the first sub-layer of the first material and of the second sub-layer of the first material are different than those used to remove portions of the first sub-layer of the first material and the second sublayer of the first material of the first superlattice; and
depositing a capping layer over the first trimmed sub-layer of the first material of the second superlattice and over the second trimmed sub-layer of the first material of the second superlattice and on an exposed surface of the substrate;
wherein, the difference between the distance between the capping layer on the first sub-layer of the first material and the capping layer on the second sublayer of the first material of the second superlattice and the distance between the capping layer on the second sub-layer of the first material of the second superlattice and the capping layer on the second substrate is less than the first difference.

2. The method of claim 1, wherein the process pressure during the etching of the first sub-layer of the first material and second sublayer of the first material on the second superlattice is lower than the process pressure during the etching of the first sub-layer of the first material and second sublayer of the first material on the first superlattice.

3. The method of claim 2, wherein the relative concentration of the gases during the etching of the first sub-layer of the first material and the second sublayer of the first material on the second superlattice is the same as the relative concentrations of the gases used to etch the first sub-layer of the first material and second sublayer of the first material on the first superlattice.

4. The method of claim 2, wherein the process time during the etching of the first sub-layer of the first material and the second sublayer of the first material on the second superlattice is longer than the process time used to etch the first sub-layer of the first material and second sublayer of the first material on the first superlattice.

5. The method of claim 2, wherein the sum of the thicknesses of the capping layer formed on the first trimmed sub-layer of the first material of the second superlattice and the thickness of the first trimmed sub-layer of the first material of the second superlattice is equal to the sum of the thicknesses of the capping layer formed on the second trimmed sub-layer of the first material of the second superlattice and the thickness of the second trimmed sub-layer of the first material of the second superlattice.

6. The method of claim 5, wherein the thickness of the capping layer formed on the first trimmed sub-layer of the first material of the second superlattice is greater than the thickness of the capping layer formed on the second trimmed sub-layer of the first material of the second superlattice.

7. A method of forming a semiconductor device on a substrate, comprising:
forming a superlattice on the substrate, the superlattice comprising alternating sub-layers of a first material comprising a semiconductor and sub-layers of a second material, wherein the thicknesses of at least a first sub-layer of the first material layers and a second sub-layer of the first material have different thicknesses, the second sublayer of the first material interposed between the first sublayer of the first material and the substrate;
removing the second material sub-layers from the superlattice;
etching the first sub layer of the first material and the second sublayer of the first material, such that a different quantity of first material is removed from the first sub layer of the first material compared to the amount of material removed from second sublayer of the first material; and
depositing a capping layer over the etched first sub layer of the first material and over the etched second sublayer of the first material, wherein the thickness of the capping layer deposited on the first sub layer of the first material is different from the thickness of the capping layer deposited on the second sub layer of the first material.

8. The method of claim 7, wherein the first sub-layer of the first material is located further from the substrate than the second sublayer of the first material, and
the thickness of the first sub-layer of the first material, prior to being etched, is greater than the thickness of the second sublayer of the first material, prior to being etched.

9. The method of claim 8, wherein the thickness of the capping layer on the etched first sub-layer of the first material is thicker than the thickness of the capping layer on the etched second sub-layer of the first material.

10. The method of claim 9, wherein the etched first sub-layer of the first material has a first side facing away from the second sublayer of the first material and a second side facing the second sub-layer of the first material;
the etched second sublayer of the first material has a first side facing the first sub-layer of the first material and a second side facing the substrate;
the capping layer is formed at least on the first and second sides of the etched first sub-layer of the first material and at least on the first and second sides of the etched second sub-layer of the first material; and
the sum of the thickness of the etched first sublayer of the first material and the thicknesses of the capping layer formed on the first and second sides thereof is equal to the sum of the thickness of the etched second sublayer of the first material and the thicknesses of the capping layer formed on the first and second sides thereof.

11. The method of claim 9, wherein the etched first sub-layer of the first material has a first side facing away from the second sublayer of the first material and a second side facing the second sub-layer of the first material;
the etched second sublayer of the first material has a first side facing the first sub-layer of the first material and a second side facing the substrate;
the capping layer is formed on the first and second sides of the etched first sub-layer of the first material and on the first and second sides of the etched second sub-layer of the first material; and
the distance between the outer surface of the capping layer on the etched first sub-layer of the first material facing the etched second sub-layer of the first material, and the surface of the capping layer on the etched second sub-layer of the first material facing the etched first sublayer of the first material, is equal to the spacing between the surface of the capping layer on the etched second sub-layer of the first material facing the substrate and the surface of the capping layer on the substrate furthest from the substrate.

12. The method of claim 10, where the etched first sub-layer of the first material and the etched second sublayer of the first material are silicon layers forming channels in an HGGA device.

13. The method of claim 11, wherein the capping layer comprises silicon germanium, and the etched first sub-layer of the first material and the capping layer thereover, and the etched second sublayer of the first material and the capping layer thereover, form channels in an HGGA device.

14. A method of forming a multi-layer semiconductor device, comprising:
providing a first substrate;
forming a superlattice on first substrate, the superlattice comprising a plurality of alternating first layers composed of a first material and second layers formed of a second material;
selectively removing the second layers of the superlattice;
exposing the first layers of the superlattice to an etchant using first process conditions and removing a portion of the first material therefrom to form trimmed first layers therefrom, wherein the quantity of material removed from different ones of the first layers are different amounts;
forming a capping layer over the first layers in the superlattice stack;
measuring at least one of the distance between the capping layers formed on the different ones of the first layers, the thicknesses of the different ones of the capping layers formed on different ones of the trimmed first layers, and the different thicknesses of the combined thickness of different ones of the trimmed first layers and the capping layer formed thereover; and
based on the differences between at least one of the distance between the capping layers formed on the different ones of the first layers, the thicknesses of the different ones of the capping layers formed on different ones of the trimmed first layers, and the different thicknesses of the combined thickness of different ones of the trimmed first layers and the capping layer formed thereover, calculating a new thickness of the trimmed first layers.

15. The method of claim 14, further comprising providing a second substrate;
forming a superlattice the second substrate, the superlattice comprising a plurality of alternating first layers composed of a first material and second layers formed of a second material, wherein at least two of the first layers of the superlattice have different thicknesses, that different thickness selected based at least in part on the differences between at least one of the distance between the capping layers formed on the different ones of the first layers on the first substrate, the thicknesses of the different ones of the capping layers formed on different ones of the trimmed first layers on the first substrate, and the different thicknesses of the combined thickness of different ones of the trimmed first layers and the capping layer formed thereover on the first substrate;
selectively removing the second layers of at least the first portion of the superlattice;
exposing the first layers of the at least first portion of the superlattice stack to an etchant and removing a portion of the first material therefrom to form trimmed first layers therefrom.

16. The method of claim 14, further comprising providing a second substrate;
forming a superlattice the second substrate, the superlattice comprising a plurality of alternating first layers composed of a first material and second layers formed of a second material, wherein the first layers have a common first thickness and the second layers have a common second thickness;
selectively removing the second layers of at least the first portion of the superlattice;
exposing the first layers of the at least first portion of the superlattice stack to an etchant and removing a portion of the first material therefrom using second process conditions different than the first process conditions to form trimmed first layers therefrom, wherein the quantity of material removed from different ones of the first layers are different amounts, and the quantity of the different amounts is selected based upon at least one of the distance between the capping layers formed on the different ones of the first layers on the first substrate, the thicknesses of the different ones of the capping layers formed on different ones of the trimmed first layers on the first substrate, and the different thicknesses of the combined thickness of different ones of the trimmed first layers and the capping layer formed thereover on the first substrate.

17. The method of claim 15, wherein the space between adjacent layers of the capping material on different trimmed first layers of the second substrate are equal to one another.

18. The method of claim 16, wherein the space between adjacent layers of the capping material on different trimmed first layers of the second substrate are equal to one another.

19. The method of claim 16, wherein the thickness of the capping layer on a layer of the first material closest to the substrate is less than the thickness of the capping layer on a layer of the first material furthest to the substrate.

20. The method of claim 15 wherein the first layers and the second layers are epitaxial layers.
